(19) United States
(12) Patent Application Publication
(10) Pub. No.: US 2008/0217054 A1
(43) Pub. Date: Sep. 11, 2008

(54) Gang Box Clip

(76) Inventor: Michael Peter Walton, (US)

Correspondence Address: MICHAEL P. WALTON, 2830 BRISTOL ROAD, WARRINGTON, PA, 18976-1408, US

(21) Appl. No.: 11/683,425

(22) Filed: Mar. 7, 2007

(51) Int. Cl. H05K 7/12

(52) U.S. Cl. 174/545

(57) ABSTRACT

A wall box device comprising a clip extending from an elongated body, for use with non metallic electrical wall boxes. The metal clip is capable of providing an attachment point for the yoke of electrical devices. The clips are secured in place (without adhesives) by a plurality of barbs extending outwardly and downward there-from. The barbs allow easy insertion of the clip onto the box, while preventing withdrawal or removal. The attachment point can include a new threaded opening to receive a machine screw, the new threaded opening taking the place of the original worn/damaged threaded opening/hub of the plastic electrical wall box.

It is emphasized that this abstract is provided to comply with the rules requiring an abstract that will allow a searcher or other reader to quickly ascertain the subject matter of the technical disclosure. It is submitted with the understanding that it will not be used to interject or limit the scope of the claims

### BACKGROUND OF THE INVENTION

1. Field of Invention

This invention relates generally to electrical wall boxes made of PVC and/or other forms of plastic or resins that are installed in partitions, walls, floors, ceilings of buildings or homes and, more particularly, to a repair clip for use with these type plastic boxes in such installations.

2. Description of Related Art and Brief Summary of the Invention

Electrical devices are installed and wired in enclosures within the walls, floors, ceilings and partitions of a building's construction.

These enclosures when installed during construction are considered “New Work” type and when installed after the initial building construction are considered “Old Work” type.

Enclosures that are installed for the purpose of housing switches, outlets and various other electrical devices of various voltages are commonly called “wall boxes” or “wall cases” or “outlet boxes” or “Gang Boxes”

These boxes are installed in each room and location and are interconnected by electrical conductors and wires which supply the electrical current to a device mounted/installed in said boxes. Each device installed in a wall box represents one gang. Thus, a wall box enclosing two devices would be a two gang wall box and a box with three devices would be a three gang box and so on.

The wall boxes facilitate the safe mounting/attachment and housing of the various devices (both low and line voltage and telecommunication) by means of two mounting attachment points (per device/gang). These mounting/attaching points are threaded female recesses, in the body of the wall case, which accept the standard 6-32 machine screws used to secure the yoke of the devices being mounted.

The electrical industry has moved from the use of metal wall boxes towards an extensive use of boxes made of PVC, plastic and other resin in new construction.

Installation of the wall boxes is made to structural members such as studs and joist composed of wood and/or metal, by means of nails and/or screws. The electrical conductors and/or circuits are then installed and enter the wall box through openings designed and intended for that purpose prior to the installation of the wall board, drywall, plaster and/or other interior wall products.

In the prior art installation described above, it has been discovered that such assemblies have certain disadvantages, namely, that over time and for various reasons, the Plastic, PVC or Resin attachment points for the two machine screws, become brittle and the threads deteriorate to a condition that the box can no longer maintain a secure attachment to the yoke of the electrical device, resulting in the device becoming loose, causing a safety hazard and rendering the wall box unserviceable and requiring removal and replacement. This removal and replacement of the wall box while installed within a finished wall is time consuming, expensive and often requires or causes damage to the wall materials and finished surface of the wall.

U.S. Pat. No. 5,627,340 has suggested an activation ring comprising retaining clips with barbs but such activation ring is “for use with electrical raceways installed in concrete floors” an entirely different purpose and application and has nothing to do with providing an attachment point having a threaded opening to receive a machine screw.

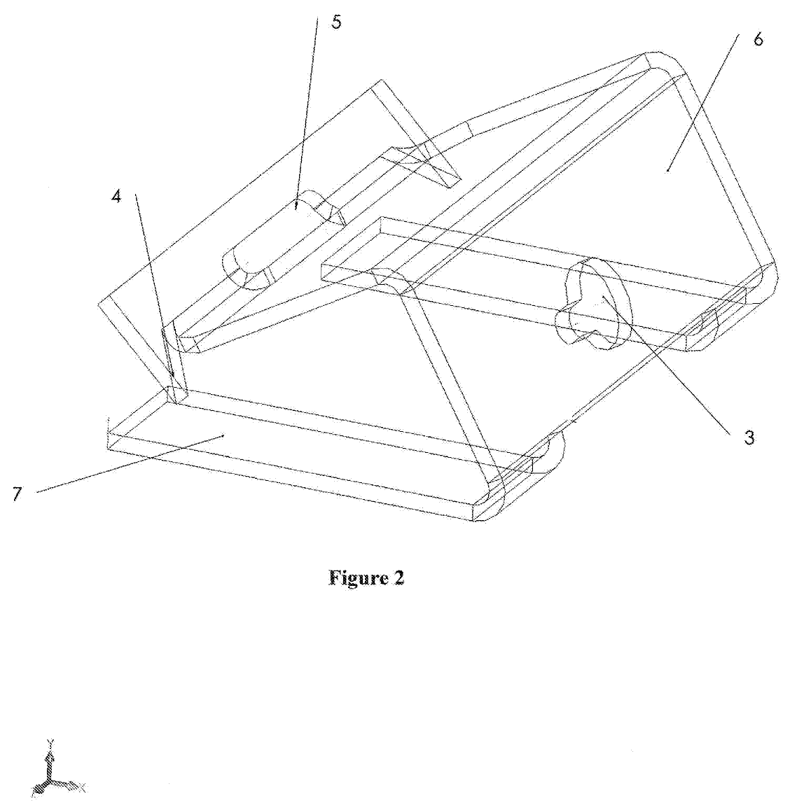

U.S. Pat. No. 5,823,821 shows an apparatus for securing an electrical outlet to an outlet box. But, at FIG. 2 of the '821 patent, the end of a flat tab (10E) has a radius and turns upward. This could result in pinching and damage of the existing electrical conductors within the outlet box. Also, the outside plate (10B) as shown in the '821 patent, would not be able to be used on or with a plastic “Nail-On” wall box.

### SUMMARY OF THE INVENTION

It is the object of this invention to provide a means to repair/restore the plastic Gang Box to a state or condition of serviceability.

In particular, an object of this invention is to provide an improved attachment point to the existing plastic wall box without requiring the removal of said existing box from within the finished wall.

In order to achieve these and other objects, the present invention comprises a metal clip assembly which has a flat bar surface capable of accepting a 6-32 machine screw thread. This metal clip is fastened in place to the wall of the plastic gang box without the use of adhesives.

In the preferred embodiment of this invention, the clip assembly is secured to the existing wall box by gripping means having a plurality of barbs extending from the metal clip, the barbs being operative to engage the plastic surface of the existing wall box and preventing the clips dislodgement.

The above stated and other objects will become apparent to those skilled in the art upon reading the following detailed description in conjunction with the appended drawings.

It is to be fully understood, however, that the assemblies disclosed herein may be easily adapted to accommodate a plurality of gang box sizes and that numerous modifications may be made in the preferred embodiments without departing from the spirit and scope of this invention. Accordingly, the scope of coverage provided by this patent should be limited only by the claims and art.

### DETAILED DESCRIPTION OF THE DRAWING AND THE INVENTION

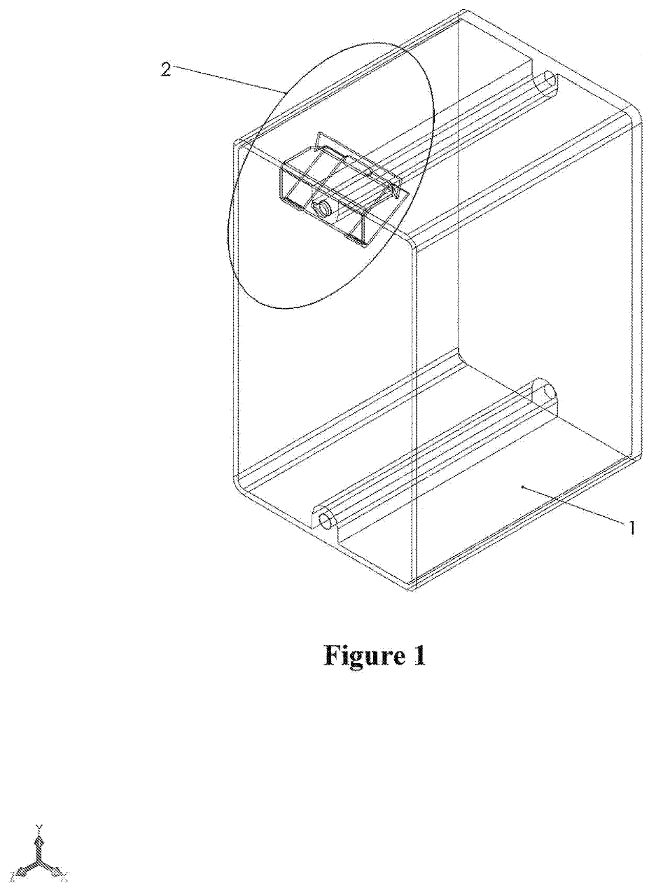

The Gang Box Clip of FIGS. 1-5 includes novel features that provide additional functionality and that are significant improvements over the clip described in the '821 patent and elsewhere in the prior art.

Attention is called to FIG. 1 which shows a gang box (item 1), preferably plastic, to which has been attached to the upper end of one of the walls the clip assembly (item 2), preferably made of metal such as steel.

FIG. 2 depicts the features and components of the clip assembly: (item 3) Keyhole Slot Threaded 6-32, (item 4) Geometrically Skewed Barb, (item 5) Release Slot/Tool Cavity, (item 6) Flat Bar w/Keyhole, (item 7) Extended Lip Guide/Support.

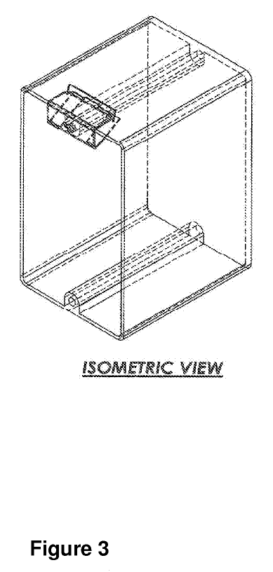

FIG. 3 depicts an Isometric View of the Clip (item 2) installed on the upper (top) wall of a plastic gang box.

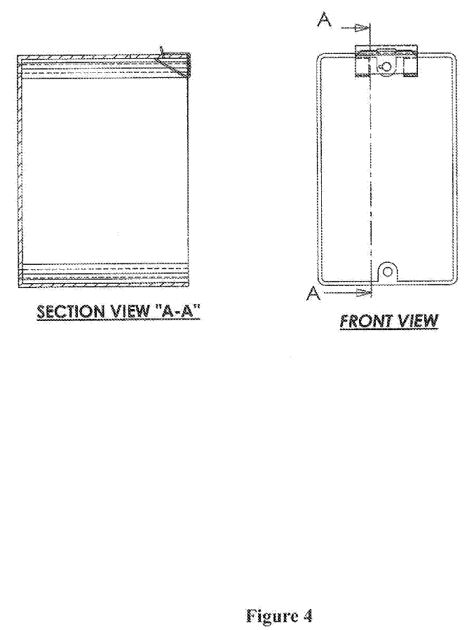

FIG. 4 presents both a Front View and sectional/cut away view (Section “A-A”) of the clip installed on the plastic gang box.

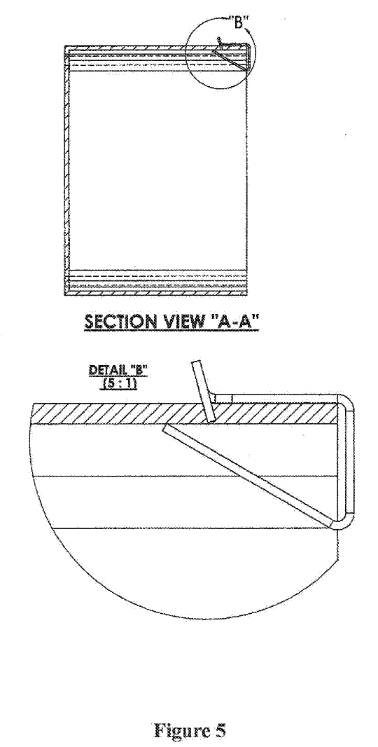

FIG. 5 shows (side view) the clip installed on the Plastic gang box and presents a enlarged view of inset “B” of Section View: A-A”

What is claimed is:

1. A clip assembly for use with electrical enclosure boxes which are fabricated, molded or otherwise constructed of PVC, plastic or other resin for use in the electrical wiring systems.

2. At least one clip in a clip assembly having gripping means for engaging at least a portion of the existing outer and/or inner wall surface of an electrical wall box, said gripping means including at least one Geometrically Skewed Barb extending laterally outwardly and downward from said clip, engaging a wall of the box and thereby resisting the removal of said clip from said box.

3. Extended Lip to facilitate guide and support during installation.

4. Release Slot creates a tool cavity for E-Z repositioning and removal

5. Key Hole Style #6-32 Right Hand Thread is strategically oriented to fit flat and lock against Gang Box.

6. Flat Bar is notched to accommodate heavy ribbed gang boxes.

7. The invention of claim 2 including a clip which is formed from spring steel and said barb is integrally formed therewith.

8. The invention of claim 2 has been appropriately sized to allow the installation of additional clips (if needed) without interference in adjacent sections of multi gang boxes.

9. The invention of claim 2 can be used to reinforce weakened existing threaded hubs/recess in plastic gang boxes and thereby reinforcing the attachment point for the yoke of the electrical device and preventing future deterioration of the existing threads.
